(19) United States
(12) Patent Application Publication
(10) Pub. No.: US 2012/0139057 A1
(43) Pub. Date: Jun. 7, 2012

(54) SEMICONDUCTOR DEVICE AND METHOD OF FABRICATING THE SAME

(75) Inventor: Masakazu Goto, Halfmoon, NY (US)

(73) Assignee: TOSHIBA AMERICA ELECTRONIC COMPONENTS, INC., Irvine, CA (US)

(21) Appl. No.: 12/961,793

(22) Filed: Dec. 7, 2010

(51) Int. Cl. H01L 27/088; H01L 21/28; H01L 29/772

(52) U.S. Cl. 257/392; 257/288; 438/591; 257/E27.061; 257/E29.242; 257/E21.209

(57) ABSTRACT

Semiconductors devices and methods of making semiconductor devices are provided. According to one embodiment, a semiconductor device, having more than two types of threshold voltages, can be employed in a logic integrated circuit with an embedded SRAM. The semiconductor device can include at least two transistors. The two transistors can be the same conductivity type (e.g., n-type or p-type). In addition, the two transistors can have disparate voltage thresholds.

### FIELD

Embodiments described herein relate generally to Metal-Oxide-Semiconductor Field Effect Transistors (MOSFETs) and methods for fabricating MOSFETs.

### BACKGROUND

Silicon large-scale integrated circuits, among other device technologies, are increasing in use in order to provide support for the advanced information society of the future. To produce an integrated circuit with highly sophisticated functions, semiconductor devices that yield high performance, such as MOSFETs or CMOSFETs (Complementary MOSFETs), can be utilized to constitute an integrated circuit.

In the design of a MOSFET, a CMOSFET, and/or similar devices, included in an integrated circuit, control of the voltage threshold can facilitate reducing leakage currents while maintaining performance. Conventionally, with one technique, the threshold voltage of a semiconductor device can be adjusted via channel ion implantation. For example, a region having a higher threshold voltage corresponds to a region having a higher implant concentration. However, higher implant concentration introduces variability in MOSFET characteristics, such as threshold voltage and drive current. This variability (referred to as random dopant fluctuation) can be especially prominent in MOSFETs having a small dimension, such as MOSFETs included in static random access memory (SRAM) cells, since random dopant fluctuation is inversely proportional to the square root of the product of the gate length and the gate width. By extending existing large scale integration technologies to smaller scales (e.g., 22 nanometers and beyond), random dopant fluctuation complicates fabrication of integrated circuits, such as embedded SRAM circuits, having a sufficient static noise margin. Another technique to modulate a threshold voltage is to add a metal element into a dielectric layer of a MOSFET gate. However, this technique can cause degradation of a gate dielectric property due to damage during the deposition and/or strip processes. Such degradation can lead to poor MOSFET reliability. Accordingly, it would be desirable to implement techniques for controlling a threshold voltage of a semiconductor device through scalable and reliable procedures.

### BRIEF DESCRIPTION OF THE DRAWINGS

FIG. 1 is a cross-sectional illustration of portions of an example MOSFET in accordance with an embodiment of the subject innovation.

FIG. 2 illustrates voltage shifts of respective semiconductor devices in accordance with various embodiments of the subject innovation.

FIGS. 3 and 4 illustrate threshold voltage modulation in accordance with various embodiments of the subject innovation.

FIG. 5 is a cross-sectional illustration of portions of an example semiconductor device in accordance with an embodiment of the subject innovation.

FIGS. 6 to 15 illustrate an example methodology for fabricating a semiconductor device in accordance with an embodiment of the subject innovation.

### DETAILED DESCRIPTION

The subject innovation provides a semiconductor device having an adjusted threshold voltage. The semiconductor device can include a high threshold voltage suitable for an SRAM cell to reduce leakage current and improve a static noise margin. In another example, the semiconductor device can include a low threshold voltage to provide enhanced performance suitable for a logic circuit. In an embodiment, a combination of germanium (Ge) and Nitrogen (N) can be employed to modulate the threshold voltage. For instance, Ge and N, included in an interfacial layer of the semiconductor device, can shift the threshold voltage.

In another embodiment, a semiconductor device, having more than two types of threshold voltages, employable in a logic integrated circuit with an embedded SRAM is provided. The semiconductor device can include at least two transistors. The two transistors can be the same conductivity type (e.g., n-type or p-type) or different conductivity types. In addition, the two transistors can have similar voltage thresholds or disparate voltage thresholds. Ge and/or N can be independently incorporated into respective interfacial layers of the two transistors such that the two transistors include varying concentrations of Ge and/or N, leading to disparate voltage thresholds. In further embodiments, methods of fabricating semiconductor devices according to at least the above are provided.

The following description and the annexed drawings set forth certain illustrative aspects of the specification. These aspects are indicative, however, of but a few of the various ways in which the principles of the specification may be employed. Other advantages and novel features of the specification will become apparent from the following detailed description of the disclosed information when considered in conjunction with the drawings.

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices may be shown in block diagram form in order to facilitate describing the claimed subject matter.

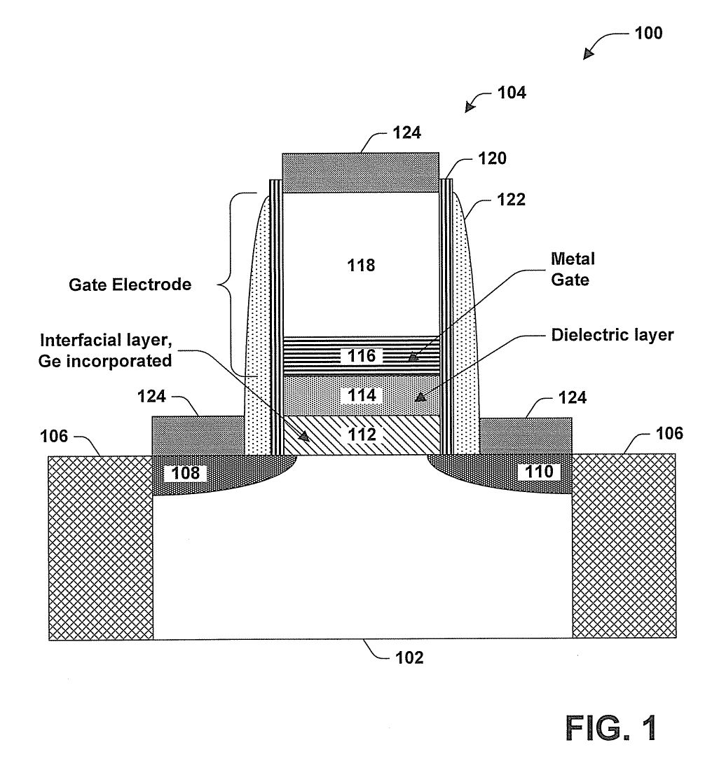

Referring first to FIG. 1, a cross-sectional illustration of an example semiconductor device 100 is provided in accordance with an embodiment. As shown in FIG. 1, semiconductor device 100 can include a substrate 102, a metal-oxide-semiconductor (MOS) transistor or MOSFET 104, and isolation features 106. MOSFET 104 can be a p-type transistor (also referred to as a pMOS or pFET) or an n-type transistor (also referred to as an nMOS or nFET). Isolation features 106 can be STIs (shallow trench isolation). Further, substrate 102 can be a silicon substrate.

Accordingly to an embodiment, MOSFET 104 can include an active region (not shown) formed on substrate 102. In addition, MOSFET 104 includes a source region 108 and a drain region 110 formed in the active region, with source region 108 and drain region 110 being separated from one another. A channel region (not shown), formed in the active region, can separate source region 108 and drain region 110. The MOSFET 104 can include an interfacial layer. (IL) 112 situated upon the channel region and located between the gate and the source/drain regions. In a specific, non-limiting example, interfacial layer 112 can contain a channel material (e.g., SI, Ge, C, etc.). Additionally, oxygen, and optionally nitrogen, can be incorporated.

MOSFET 104 can further include a dielectric layer 114. Dielectric layer 114 can include a gate or high-k dielectric having a high dielectric constant, k. For instance, dielectric layer 114 can be constructed using a variety of metal-Si materials and/or any other suitable material(s) having a high dielectric constant. For example, materials that can be utilized of dielectric layer 114 include compositions having the following chemical formulae: HfₓSi₁₋ₓO₂, HfₓSi₁₋ₓON, ZrₓSi₁₋ₓO₂, ZrₓSi₁₋ₓON, LaₓSi₁₋ₓO₂, LaₓSi₁₋ₓON, GdₓSi₁₋ₓO₂, GdₓSi₁₋ₓON, HfZrSiO, HfZrSiON, HfLaSiO, and HfGdSiO, where x is between 0 and 1. It should be appreciated, however, that the preceding list is provided merely by way of example and that other compositions could also be utilized.

MOSFET 104 can further include a gate electrode 116 and/or 118 situated on the dielectric layer 114. In an embodiment, the gate electrode can include a metal gate or first conductive layer 116 and a patterned electrode or second conductive layer 118. However, it is to be appreciated that gate electrode can includes single conductive layer (e.g., either first layer 116 or second layer 118). In a further non-limiting example, the gate electrode can be formed using a metal or metallic alloy. Specific examples of compositions that can be utilized for the gate electrode include metals such as Ti, Hf, Ta, W, Al, Ru, Pt, Re, Cu, Ni, Pd, Ir, and/or Mo; nitrides and carbides such as TiN, TaN, TiC, TaC, WN, WC, and/or HfN; conductive oxides such as RuOx and/or ReOx; metal-metal-alloys such as Ti—Al, Hf—Al, Ta—Al, and/or TaAlN; multi-stacked structures of the preceding compositions, such as TiN/W, TiN/Ti—Al, Ta/TiN/Ti—Al, or the like. It should be appreciated, however, that the preceding list is provided by way of example and that other compositions could be utilized for the gate electrode.

In a further embodiment, MOSFET 104 can include a first spacer 120, a second spacer 122, and a silicide layer 124. The silicide layer 124 can be stacked upon the gate electrode and/or upon the source region 108 and drain region 110. The silicide layer 124 can be constructed with a Si and metal-silicide, such as NiSiₓ, PtSiₓ, PdSiₓ, CoSiₓ, TiSiₓ, WSiₓ, etc. It should be appreciated, however, that the preceding list is provided by way of example and that other compositions could be utilized for silicide layer 124.

With respect to the construction of semiconductor device 100, as well as various other semiconductor devices as illustrated and described herein, it can be appreciated that the formation of gate electrodes having the respective optimum threshold voltages according to device structure, conductivity types, operation voltage, etc., can be complicated and introduce negative effects. Accordingly, it can be appreciated that mechanisms for controlling a threshold voltage of a semiconductor device through scalable and reliable procedures are desirable. Thus, according to an embodiment, an additional element, which is not a main component of interfacial layers in a semiconductor device, can be doped in the interfacial layers. In one example, a shift in the threshold voltage can be achieved based, at least in part, on an amount of the additional element introduced to the interfacial layer. By constructing a semiconductor device in this manner, it can be appreciated that a work function can be easily modulated via less variable and more reliable procedures as compared to conventional methods, resulting in improvement of device performance.

With respect to the above and the embodiments that follow, it can be appreciated that while FIG. 1 and the respective other illustrations provided herein show examples of semiconductor devices for which the embodiments can be implemented, the embodiments described herein can also be applicable for novel channel devices (e.g., SiGe, SiC, SiGeC, III-V materials, etc.), novel device structures (e.g., Si on insulator (SOI), 3-dimensional transistors (e.g., finFET, verticalFET, nanowire, nanotube, . . . ), etc.), and/or any other suitable device type(s).

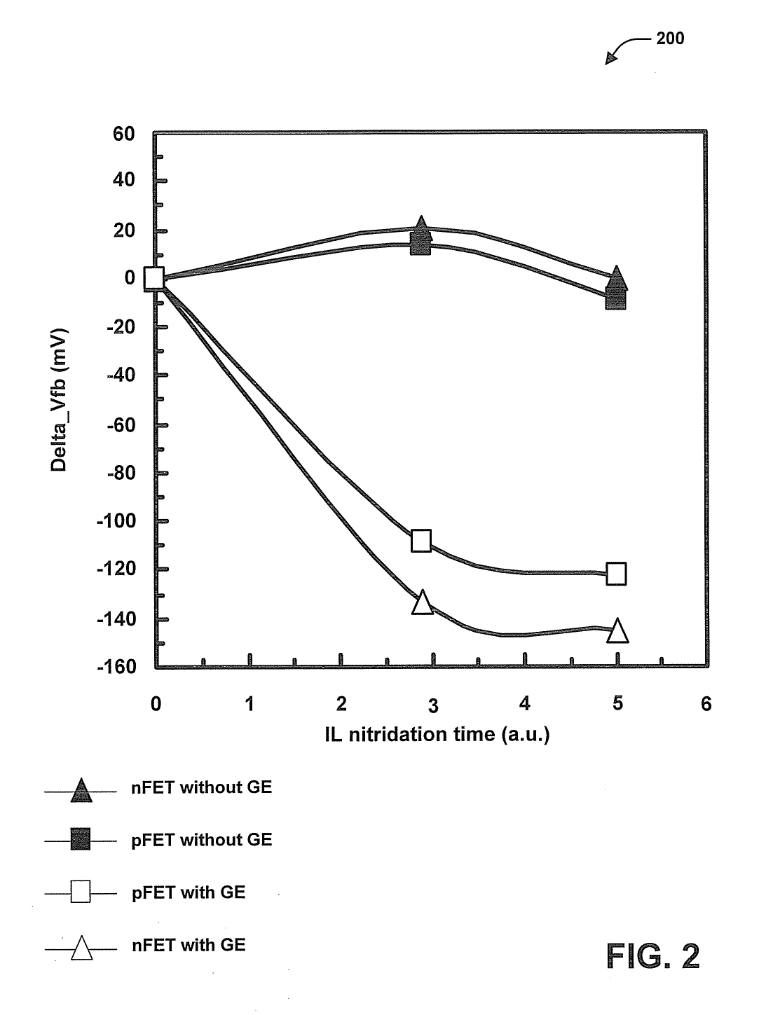

According to an embodiment, enhanced threshold voltage modulation for semiconductor device 100 can be achieved by introducing an additional element to interfacial layer 112. By way of example, as shown in FIG. 1, Ge can be incorporated into interfacial 112, thereby effecting either a positive or negative threshold voltage shift for semiconductor 100, depending on conductivity type. This technique is in contrast to conventional semiconductor fabrication techniques, where prolonged nitridation via ion implantation or incorporation of a metal element into gate dielectrics are employed. For example, as shown in FIG. 2, graph 200 depicts a shift or delta (in millivolts (mV)) in a flat-band voltage (upon which a threshold voltage depends) relative to an interfacial layer nitridation time (in arbitrary units (a.u.)). As nitridation time increases, a concentration of nitrogen in the interfacial layer increases. Graph 200 illustrates the shift in flat-band voltage when Ge is incorporated into the interfacial layer and when Ge is not incorporated. In addition, graph 200 depicts flat-band voltage shifts of both pFETs and nFETs. In an embodiment, a negative shift in the flat-band voltage corresponds to an increase of the absolute number of threshold voltage (i.e. higher threshold voltage) for pFETs and to a decrease of the absolute number of threshold voltage (i.e. lower threshold voltage) for nFETs.

As shown in graph 200, incorporation of Ge to the interfacial layer can effect a negative shift in flat-band voltage for both nFETs and pFETs. A lack of Ge in the interfacial layer results in an initial positive shift followed by a negative shift after prolonged nitridation. According to an embodiment, a peak concentration of Ge and N can occur at time=5 and can be approximately 5×10¹⁵ atoms/cm² and 2×10¹⁵ atoms/cm², respectively.

Referring again to FIG. 1, and as noted above, Ge, in one embodiment, can be incorporated into the interfacial layer 112, which can include a SiON material. In one example, Ge in interfacial layer 112 can be utilized to modulate the threshold voltage of semiconductor device 100. For instance, Ge can increase the threshold voltage when semiconductor device 100 is a pFET and can decrease the threshold voltage when semiconductor device 100 is an nFET.

Referring next to FIG. 3, illustrated is a portion of a semiconductor device 300 after a first step in modulating threshold voltages in accordance with various embodiments. Semiconductor 300 can include a substrate 302 having a first active region 304 and a second active region 306 separated by an isolation 308 (e.g., a shallow trench isolation). Respective transistors can be fabricated upon the active regions 304 and 306. In an embodiment, a threshold voltage of a transistor on first active region 304 differs from a threshold voltage of a transistor on the second active region 306. To accomplish disparate threshold voltages, an additional element, such as Ge or any other suitable material, can be incorporated into an interfacial layer of semiconductor device 300. In an example, a mask 310 can cover second active region 306 while a Ge-incorporated layer 312 is formed on the first active region 304. According to an example, Ge-incorporated layer 312 can be a SiGe epitaxial layer formed via epitaxy. In another example, Ge-incorporated layer 312 can be formed via ion implantation of Ge.

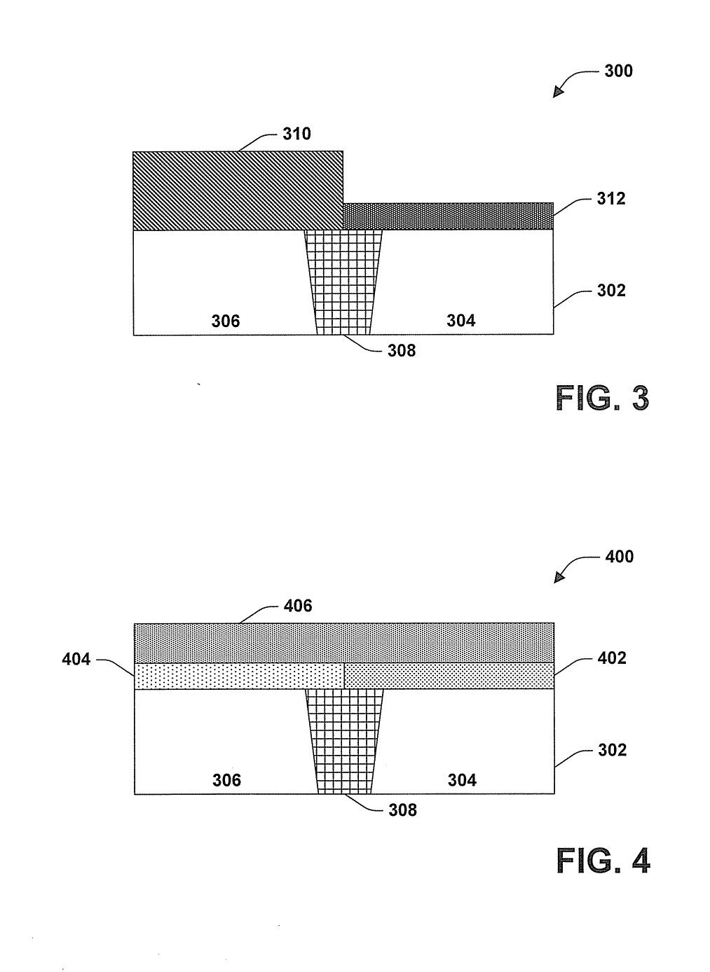

Turning to FIG. 4, illustrated is a portion of a semiconductor device 400 after a subsequent step, following the step depicted in FIG. 3. FIG. 4 illustrates substrate 302 having first active region 304 and second active region 306 separated by isolation 308 as described above. An interfacial layer can be formed on first active region 304 and second active region 306. In an example, the interfacial layer can be formed by nitridation of an oxide layer (e.g., SiO) deposited on substrate 302 to produce a SiON interfacial layer. Since Ge-incorporated layer 312 is formed as described above with respect to FIG. 3, formation of the interfacial layer results in a Ge-incorporated interfacial layer 402 on first active region 304 and an interfacial layer 404 lacking Ge on second active region 306. The differences between interfacial layers 402 and 404 provide disparate threshold voltages as described above. A dielectric layer 406 can be deposited on the interfacial layers 402 and 404.

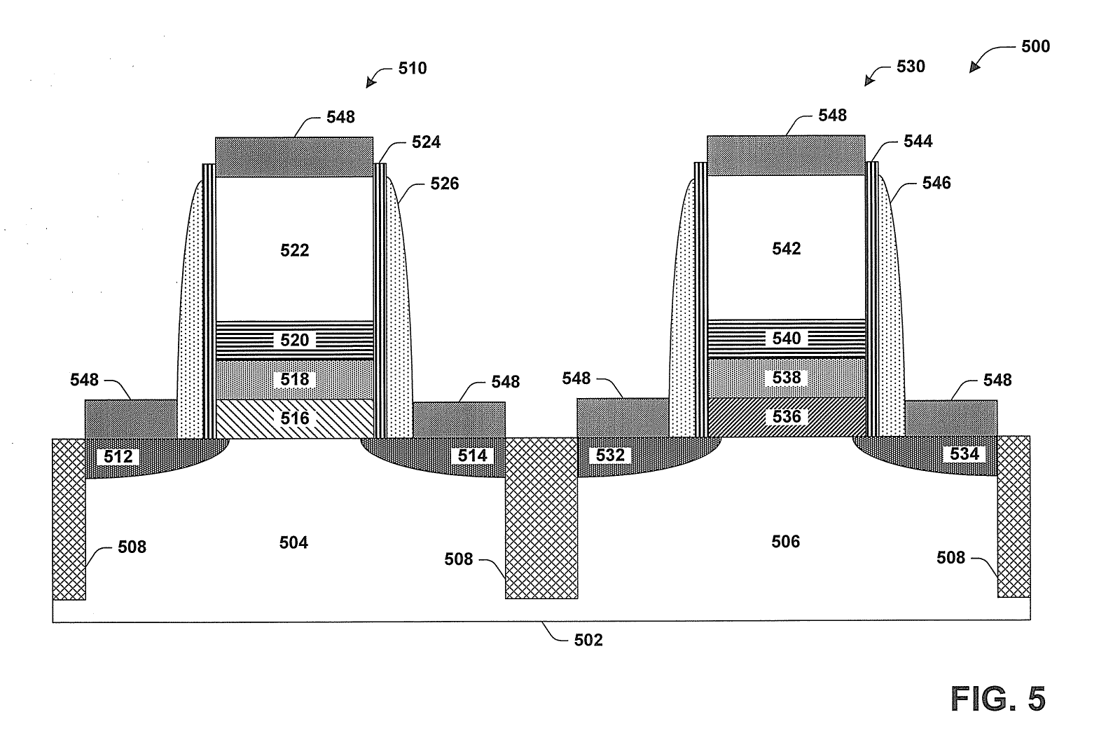

Referring to FIG. 5, a cross-sectional illustration of an example semiconductor device 500 is provided in accordance with an embodiment. As shown in FIG. 5, semiconductor device 100 can include a first transistor or MOSFET 510 and a second transistor or MOSFET 530. Semiconductor device 500 can also include a silicon substrate 502 that includes a first active region 504 and a second active region 506 separated by isolation features 508. MOSFET 510 can be constructed on first active region 504 of substrate 502 and MOSFET 530 can be constructed on second active region 506.

According to an embodiment, MOSFET 510 and MOSFET 530 can be the same conductivity type. For example, MOSFET 510 and MOSFET 530 can both be pFETs or nFETs. In a further embodiment, MOSFET 510 and MOSFET 530 can have disparate threshold voltages while being the same conductivity type. In addition, MOSFET 510 and MOSFET 530 can be different conductivity types (e.g., MOSFET 510 is a pFET and MOSFET 530 is an nFET or vice versa). In this situation, MOSFET 510 and MOSFET 530 can have similar threshold voltages despite being different conductivity types.

According to an embodiment, MOSFET 510 can include first active region 504 formed on substrate 502. In addition, MOSFET 510 includes a source region 512 and a drain region 514 formed in first active region 504. MOSFET 510 can include an interfacial layer 516 situated upon a channel region of first active region 504. In a specific, non-limiting example, interfacial layer 516 can contain a channel material (e.g., Si). Additionally, oxygen, and optionally nitrogen, can be incorporated such that interfacial layer 516 is a layer of SiON.

MOSFET 510 can further include a dielectric layer 518. Dielectric layer 518 can include a gate or high-k dielectric having a high dielectric constant, k. For instance, dielectric layer 518 can be constructed using a variety of metal-Si materials and/or any other suitable material(s) having a high dielectric constant. For example, materials that can be utilized of dielectric layer 518 include compositions having the following chemical formulae: HfₓSi₁₋ₓO₂, HfₓSi₁₋ₓON, ZrₓSi₁₋ₓO₂, ZrₓSi₁₋ₓON, LaₓSi₁₋ₓO₂, LaₓSi₁₋ₓON, GdₓSi₁₋ₓO₂, GdₓSi₁₋ₓON, HfZrSiO, HfZrSiON, HfLaSiO, and HfGdSiO, where x is between 0 and 1. It should be appreciated, however, that the preceding list is provided merely by way of example and that other compositions could also be utilized.

MOSFET 510 can further include a gate electrode situated on the dielectric layer 518. In an embodiment, the gate electrode can include a metal gate or first conductive layer 520 and a patterned electrode or second conductive layer 522. However, it is to be appreciated that gate electrode can include a single conductive layer (e.g., either first layer 520 or second layer 522). In a further non-limiting example, the gate electrode can be formed using a metal or metallic alloy. Specific examples of compositions that can be utilized for the gate electrode include metals such as Ti, Hf, Ta, W, Al, Ru, Pt, Re, Cu, Ni, Pd, Ir, and/or Mo; nitrides and carbides such as TiN, TaN, TiC, TaC, WN, WC, and/or HfN; conductive oxides such as RuOx and/or ReOx; metal-metal-alloys such as Ti—Al, Hf—Al, Ta—Al, and/or TaAlN; multi-stacked structures of the preceding compositions, such as TiN/W, TiN/Ti—Al, Ta/TiN/Ti—Al, or the like. It should be appreciated, however, that the preceding list is provided by way of example and that other compositions could be utilized for the gate electrode.

In a further embodiment, MOSFET 104 can include a first spacer 524, a second spacer 526, and a silicide layer 548. The silicide layer 548 can be stacked upon the gate electrode and/or upon the source region 512 and drain region 514. The silicide layer 548 can be constructed with a Si and metal-silicide, such as NiSiₓ, PtSiₓ, PdSiₓ, CoSiₓ, TiSiₓ, WSiₓ, etc. It should be appreciated, however, that the preceding list is provided by way of example and that other compositions could be utilized for silicide layer 548.

Similar to MOSFET 510, MOSFET 530 can include a source region 532 and a drain region 534 formed on second active region 506. In addition, MOSFET 536 can include an interfacial layer 536 upon a channel region of second active region 506. Stacked upon the interfacial layer 536 can be a dielectric layer 538 similar to dielectric layer 518 of MOSFET 510. MOSFET 530 can also include a gate electrode that includes a metal gate or first conductive layer 540 and a second conductive layer 542. MOSFET 530 also includes a first spacer 544 and a second spacer 546.

According to an embodiment, MOSFET 530 can have a different threshold voltage relative to MOSFET 510. In a further embodiment, MOSFET 530 and MOSFET 510 can be of the same conductivity type (e.g., both pFETs or both nFETs). In one example, MOSFET 510 can have a first threshold voltage and MOSFET 530 can include a second threshold voltage. When MOSFETs 510 and 530 are pFETs, the first threshold voltage is low and the second threshold voltage is high. Accordingly, as a pFET, MOSFET 510 can be employed for logic circuits as the low threshold voltage provides improved performance. MOSFET 530 can be employed for SRAM cells as the high threshold voltage reduces leakage current and enables a higher static noise margin. In another example, when MOSFETs 510 and 530 are nFETs, the first threshold voltage is high and the second threshold voltage is low. Accordingly, as nFETs, MOSFET 510 can be employed for SRAM cells and MOSFET 530 can be employed for logic circuits.

According to an embodiment, the aforementioned differences in the first and second threshold voltages are achieved via incorporation of an additional element to the interfacial layer of one of the MOSFETs. In one example, interfacial layer 516 of MOSFET 510 and interfacial layer 536 of MOSFET 530 can both include Si, O, N (e.g., a SiON layer). In addition, to SiON, interfacial layer 536 can include Ge, which as described above, shifts the threshold voltage of pFETs higher and shifts the threshold voltage of nFETs lower when incorporated into the interfacial layer.

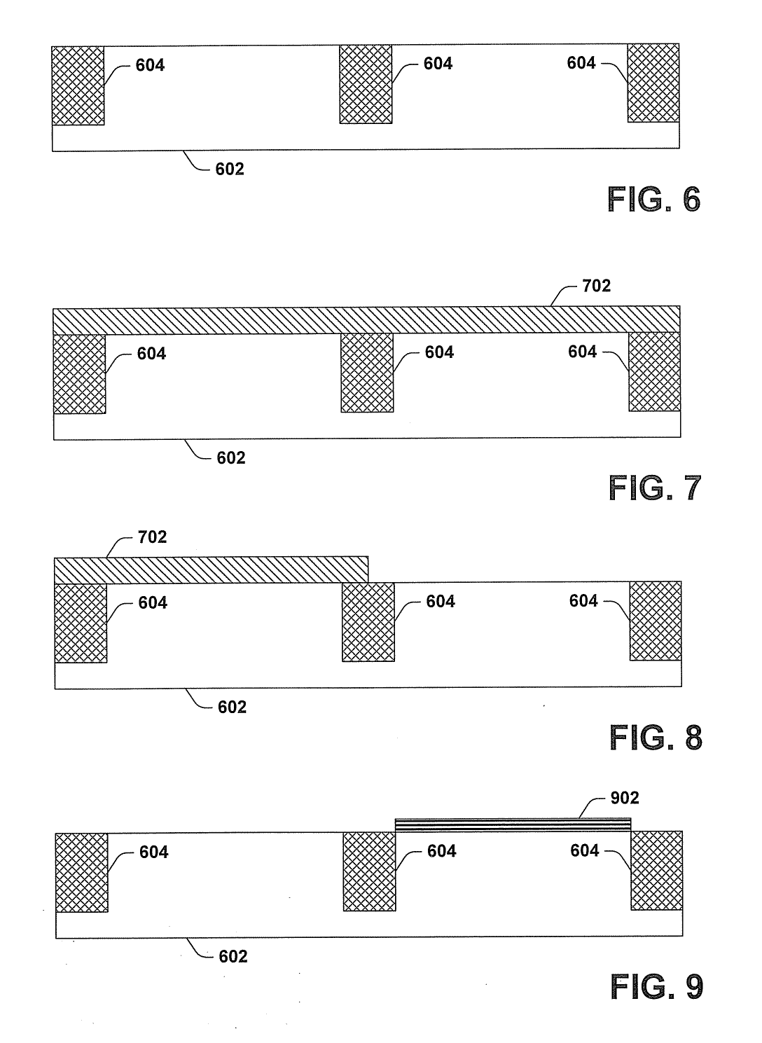

Turning next to FIGS. 6-15, various techniques for fabricating a semiconductor device having a plurality of threshold voltages are presented. It should be appreciated, however, that the semiconductor can be created using any suitable process or combination of processes and that the following description is provided by way of a non-limiting example. Further, it should be appreciated that the processes presented in the following description can be utilized to fabricate any suitable product(s) and are not intended to be limited to the semiconductor devices described above.

With reference first to FIG. 6, a first example step of semiconductor fabrication in accordance with an embodiment is illustrated. As shown in FIG. 6, well isolation can be performed to separate active regions on a silicon substrate 602. In an embodiment, well isolation can include formation of isolation features such as shallow trench isolations (STIs) 604. In one example, STIs 604 can be formed by depositing a pad oxide and a protective nitride layer over substrate 602. An opening can be formed in the protective nitride layer and substrate 602 can be etched to form a trench. The trench can be filled with a dielectric, such as silicon dioxide for example. Planarization can occur followed by removal of the protective nitride and pad oxide.

As shown in FIG. 7, a hard mask 702 can be formed on substrate 602. The hard mask 702 can be formed, for example, by deposition of tetraethyl orthosilicate (TEOS) which can convert into silicon dioxide (SiO₂) in the presence of water. However, it is to be appreciated that hard mask 702 can include other materials in addition to silicon dioxide and can be formed via alternative processes. Turning to FIG. 8, illustrated is a result after patterning of the hard mask 702. Hard mask 702 can be etched or patterned via photolithography and a rinse of dilute hydrofluoric acid (DHF). Patterning exposes a first active region of substrate 602 while maintaining a cover of hard mask 702 on a second active region of substrate 602.

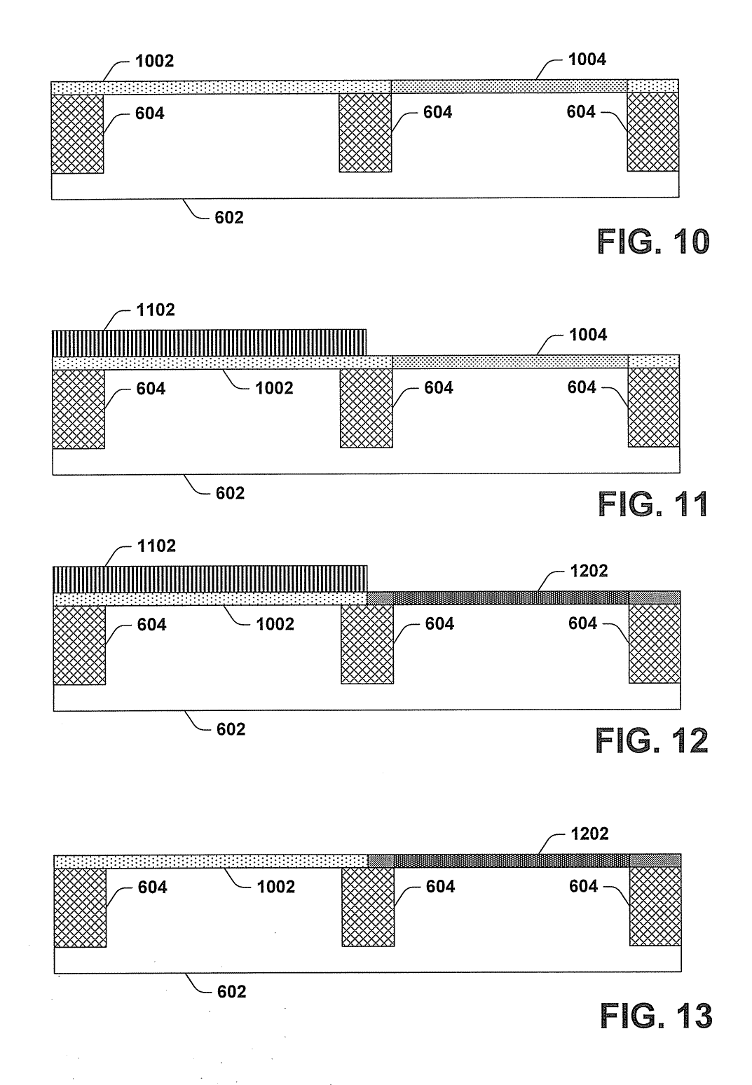

In an embodiment, after patterning, a layer 902 containing Ge can be formed and the remaining hard mask 702 can be stripped, the result of which is depicted in FIG. 9. Ge layer 902 can be formed via epitaxy of a SiGe onto the first active region of substrate 602. In addition, the hard mask 702 can be stripped via etching with DHF. FIG. 10 illustrates a result after formation of a SiON interfacial layer on substrate 602. The interfacial layer can be formed via oxidation and/or nitridation. Due to the earlier formation of Ge layer 902, the interfacial layer includes a portion 1002, on the second active region, containing SiON and a portion 1004, on the first active region, containing Ge in addition to SiON.

A hard mask 1102 can be formed on the interfacial layer over the second active region as shown in FIG. 11. The hard mask 1102 can be a SiN layer formed via SiN deposition. The portion 1004 of the interfacial layer over the first active region can be exposed to a second nitridation process (e.g., via plasma nitridation). The second nitiridation process results in an interfacial layer 1202, as illustrated in FIG. 12, containing Ge and having a higher concentration of N relative to interfacial layer 1002. Subsequently, the hard mask 1102 can be stripped as shown in FIG. 13 via, for example, etching with hot phosphoric acid.

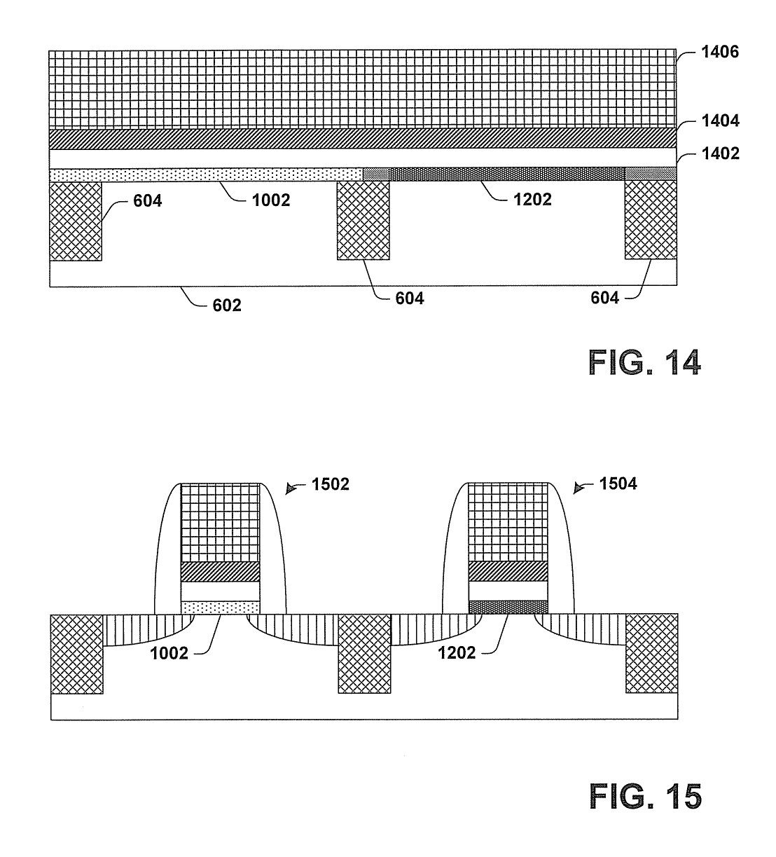

Turning to FIG. 14, a gate stack can be formed on the interfacial layer via chemical vapor deposition and/or physical vapor deposition. The gate stack can include a dielectric layer 1402 (e.g., a high-k dielectric), a metal gate layer or first conductive layer 1404, and a second conductive layer 1406. A conventional transistor fabrication process can be employed to create gates or MOSFETs 1502 and 1504 as shown in FIG. 15. MOSFETs 1502 and 1504 can be p-type transistors and/or n-type transistors. In an embodiment, MOSFET 1502 includes interfacial layer 1002 having a relatively lower concentration of nitrogen. MOSFET 1504 includes interfacial layer 1202 having Ge incorporated therein and a relatively higher concentration of nitrogen. Due to the differences in interfacial layer 1002 and interfacial layer 1202, MOSFETs 1502 and 1504 have disparate threshold voltages.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

Further, while certain embodiments have been described above, it is to be appreciated that these embodiments have been presented by way of example only, and are not intended to limit the scope of the claimed subject matter. Indeed, the novel methods and devices described herein may be made without departing from the spirit of the above description. The accompanying claims and their equivalents are intended to cover such forms or modifications as would fall within the scope and spirit of the subject innovation.

In addition, it should be appreciated that while the respective methodologies provided above are shown and described as a series of acts for purposes of simplicity, such methodologies are not limited by the order of acts, as some acts can, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

what is claimed is:

1. A semiconductor device having a plurality of threshold voltages, comprising:
a substrate;
a first transistor, on the substrate, having a first threshold voltage, the first transistor comprising:
a first interfacial layer formed on a first channel region of the substrate;
a first gate dielectric layer formed on the first interfacial layer; and
a first gate electrode formed on the first gate dielectric layer; and
a second transistor, on the substrate, having a second threshold voltage, the second transistor comprising:
a second interfacial layer formed on a second channel region of the substrate, wherein the second interfacial layer having an additional element incorporated therein which is not present in the first interfacial layer and is disparate from Si, O, and N;
a second gate dielectric layer formed on the second interfacial layer; and
a second gate electrode formed on the second gate dielectric layer,
wherein the first threshold voltage and the second threshold voltage are different and the first transistor and the second transistor have an identical conductivity type.

2. The semiconductor device of claim 1, wherein the first gate dielectric layer and the second gate dielectric layer are substantially the same material, the first gate electrode and the second gate electrode are substantially the same material, and the first interfacial layer and the second interfacial layer are substantially the same material except for the additional element incorporated in the second interfacial layer.

3. The semiconductor device of claim 1, wherein the first transistor and the second transistor are p-type transistors.

4. The semiconductor device of claim 3, wherein the first threshold voltage is less than the second threshold voltage.

5. The semiconductor device of claim 4, wherein the first transistor is included in a static random access memory (SRAM) cell and the second transistor is included in a logic circuit.

6. The semiconductor device of claim 1, wherein the first transistor and the second transistor are n-type transistors.

7. The semiconductor device of claim 6, wherein the first threshold voltage is greater than the second threshold voltage.

8. The semiconductor device of claim 7, wherein the first transistor is included in a logic circuit and the second transistor is included in an SRAM cell.

9. The semiconductor device of claim 1, wherein the additional element comprises germanium (Ge).

10. The semiconductor device of claim 9, wherein a peak concentration of Ge in the second interfacial layer is about 5×10¹⁵ atoms/cm².

11. The semiconductor device of claim 1, wherein the first interfacial layer and the second interfacial layer comprises at least silicon, nitrogen, and oxygen, and wherein a concentration of nitrogen in the second interfacial layer is greater than a concentration of nitrogen in the first interfacial layer.

12. The semiconductor device of claim 11, wherein a peak concentration of N in the second interfacial layer is about 2×10¹⁵ atoms/cm².

13. A semiconductor device, comprising:
a substrate; and
a Metal-Oxide-Semiconductor (MOS) transistor, comprising:
a semiconductor region formed on the substrate;
a source region and a drain region formed in the semiconductor region, wherein the source region and the first drain region are separated from each other;
a channel region formed in the semiconductor region that separates the source region and the drain region;
an interfacial layer formed on the channel region having an additional element incorporate therein that is disparate from Si, O, and N at a peak concentration of about 5×10¹⁹ atoms/cm²;
a gate dielectric layer formed on the interfacial layer; and
a gate electrode formed on the gate dielectric layer.

14. The semiconductor device of claim 13, wherein the additional element is Ge.

15. The semiconductor device of claim 13, wherein a peak concentration of N in the interfacial layer is about 2×10¹⁵ atoms/cm².

16. The semiconductor device of claim 13, wherein the MOS transistor is a p-type transistor incorporated into an SRAM cell.

17. The semiconductor device of claim 13, wherein the transistor is an n-type transistor incorporated into a logic circuit.

18. A method of fabricating a semiconductor device having a first transistor and a second transistor of identical conductivity types but having disparate threshold voltages, comprising:
forming an epitaxial layer on a first channel region of a substrate, the first channel region being associated with the first transistor, the epitaxial layer including a Ge atom;
forming an interfacial layer on the substrate, wherein the interfacial layer having a first portion associated with the first transistor and a second portion associated with the second transistor, the first portion being incorporated with the epitaxial layer;
forming a gate stack on the first portion and the second portion of the interfacial layer; and
etching the gate stack to respectively form the first transistor and the second transistor.

19. The method of claim 18, further comprising:
forming a hard mask on the substrate; and
patterning the hard mask to expose the first channel region of the substrate.

20. The method of claim 18, further comprising:
forming a hard mask on the second portion of the interfacial layer; and
performing a nitridation on the first portion of the interfacial layer.
